(19) United States
(12) Patent Application Publication
(10) Pub. No.: US 2009/0176356 A1
(43) Pub. Date: Jul. 9, 2009

(54) METHODS FOR FABRICATING SEMICONDUCTOR DEVICES USING THERMAL GRADIENT-INDUCING FILMS

(75) Inventors: Rohit PAL, Fishkill, NY (US); Jon KLUTH, Hopewell Junction, NY (US); David BROWN, Pleasant Valley, NY (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 11/971,481

(22) Filed: Jan. 9, 2008

(51) Int. Cl. H01L 21/22

(52) U.S. Cl. 438/550; 257/E21.135

(57) ABSTRACT

Methods for fabricating semiconductor devices using thermal gradient-inducing films are provided. One method comprises providing a substrate having a first region and a second region and forming a film overlying the second region and exposing the first region. The substrate is subjected to a thermal process wherein the film induces a predetermined thermal gradient between the first region and the second region.

### FIELD OF THE INVENTION

The present invention generally relates to methods of fabricating semiconductor devices, and more particularly relates to methods for fabricating semiconductor devices using thermal gradient-inducing films.

### BACKGROUND OF THE INVENTION

The majority of present day integrated circuits (ICs) are implemented by using a plurality of interconnected field effect transistors (FETs), also called metal oxide semiconductor field effect transistors (MOSFETs), or simply MOS transistors. An MOS transistor includes a gate electrode as a control electrode disposed overlying a semiconductor substrate and spaced apart source and drain regions disposed within the substrate and between which a current can flow. A control voltage applied to the gate electrode controls the flow of current through a channel within the substrate between the source and drain regions.

Epitaxially-grown films often are used in MOS transistors to modify the performance of such transistors. For example, an epitaxially-grown silicon-containing film can be used to increase the mobility of majority carriers through the channel of an MOS transistor by inducing stresses in the channel. The mobility of holes, the majority carrier in a P-channel MOS (PMOS) transistor can be increased by applying a compressive longitudinal stress to the channel, especially when the transistor is fabricated on a silicon wafer. It is well known that a compressive longitudinal stress can be applied to a silicon MOS transistor by embedding an epitaxially-grown material such as silicon germanium (SiGe) at the ends of the transistor channel. Similarly, the mobility of electrons, the majority carrier in an N-channel MOS (NMOS) transistor, can be increased by applying a tensile longitudinal stress to the channel. Such a stress can be applied to a silicon MOS transistor by embedding a material such as epitaxially-grown silicon doped with carbon (SiC) at the ends of the transistor channel. Such methods typically require the etching of trenches into the silicon substrate and the selective epitaxial deposition of silicon germanium and/or silicon carbon therein.

However, subsequent high-temperature processes, such as rapid thermal annealing (RTA) and laser spike annealing (LSA), that are used in semiconductor device fabrication, for example, for thermal dopant activation, may significantly compromise the benefits of SiGe, SiC, and other strained layers. Temperatures used in RTA and LSA can be in excess of 1000° C. Carbon-doped silicon is very sensitive to such high temperatures and, when subjected thereto, relaxes to such an extent that the stress it exerts on the channels of MOS transistors is significantly compromised. The extent to which SiGe relaxes is dependent on the concentration of germanium in the strained layer. The greater the germanium concentration, the greater the extent of relaxing. Accordingly, if a relatively high germanium concentration is used in a strained SiGe layer, subsequent annealing should be performed at temperatures that will not cause the SiGe to significantly relax. However, annealing at such temperatures may result in an unsatisfactory activation of impurity dopants and, hence, faulty operation of the device.

Such high annealing temperatures also have detrimental effects on the dopant species of P-channel and N-channel devices. The silicon of an MOS transistor typically is doped with P-type conductivity-determining impurities for the fabrication of an NMOS transistor or with N-type conductivity-determining impurities for the fabrication of a PMOS transistor. However, such dopants diffuse to different distances for the same annealing conditions. For example, dopant ions such as boron and arsenic often are used to form source and drain regions for PMOS transistors and NMOS transistors, respectively. However, arsenic is a larger atom than boron and, hence, boron diffuses faster than arsenic at the same annealing temperatures. The differences in dopant profiles of the various source and drain regions can have significant effect on the operation of the resulting MOS transistors.

Similar detrimental effects may result when dopants are subjected to different thermal budgets. For example, if the doping and activation of a first region of an MOS transistor is performed before the doping and activation of a second region, the dopants of the first region will be subjected to a different, and higher, thermal budget than the dopants of the second region. This higher thermal budget may cause the dopants of the first region to diffuse further than desired, which, again, may have significant detrimental effects on the operation of the resulting MOS transistors.

Accordingly, it is desirable to provide methods for fabricating semiconductor devices that induce predetermined thermal gradients to protect regions of a substrate from high thermal processes. In addition, it is desirable to provide methods for fabricating semiconductor devices that use thermal gradient-inducing films to protect various regions of a substrate from high thermal processes. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for fabricating a semiconductor device in accordance with an exemplary embodiment of the present invention is provided. The method comprises providing a substrate having a first region and a second region and forming a film overlying the second region and exposing the first region. The substrate is subjected to a thermal process wherein the film induces a predetermined thermal gradient between the first region and the second region.

A method of fabricating a semiconductor device in accordance with another exemplary embodiment of the present invention is provided. The method comprises providing a substrate having a first region and a second region, and forming a film overlying the first region and the second region. A first portion of the film is removed from the first region and a second portion of the film is left overlying the second region. The substrate is subjected to a thermal process wherein the film causes the first region to experience a first predetermined temperature and the second region to experience a second predetermined temperature.

A method of fabricating a semiconductor device in accordance with a further exemplary embodiment of the present invention is provided. The method comprises providing a substrate having a first region and a second region and subjecting the substrate to a thermal process while inducing a predetermined thermal gradient between the first region and the second region.

### BRIEF DESCRIPTION OF THE DRAWINGS

The present invention will hereinafter be described in conjunction with the following drawing figures, wherein like numerals denote like elements, and

FIGS. 1-2 and 6 illustrate a method for fabricating a semiconductor device using a thermal gradient-inducing film, in accordance with an exemplary embodiment of the present invention;

FIG. 3 illustrates a method for fabricating a semiconductor device using a thermal gradient-inducing film, in accordance with another exemplary embodiment of the present invention;

FIG. 4 illustrates a method for fabricating a semiconductor device using a thermal gradient-inducing film, in accordance with a further exemplary embodiment of the present invention; and

FIG. 5 illustrates a method for fabricating a semiconductor device using a thermal gradient-inducing film, in accordance with yet another exemplary embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

The methods in accordance with exemplary embodiments of the present invention utilize films that induce a predetermined thermal gradient between a first region and a second region of a substrate of a semiconductor device. In one exemplary embodiment of the invention, the film overlies a second region of the substrate, with the first region exposed. The film is configured so that, upon exposure to a thermal process, the first region is subjected to a higher temperature than the second region. In this regard, the second region is protected from thermal energy that would compromise physical, chemical, and/or electrical properties of the second region. In another exemplary embodiment, the film is configured so that, upon exposure to a thermal process, the first region is subjected to a lower temperature than the second region. In this regard, thermal energy can be concentrated at the second region to maximize the temperature the second region experiences. In another exemplary embodiment, two films can be used to induce a predetermined thermal gradient. In this regard, a first region can be protected from high temperatures while thermal energy is concentrated at a second region to produce a predetermined thermal gradient between the two regions.

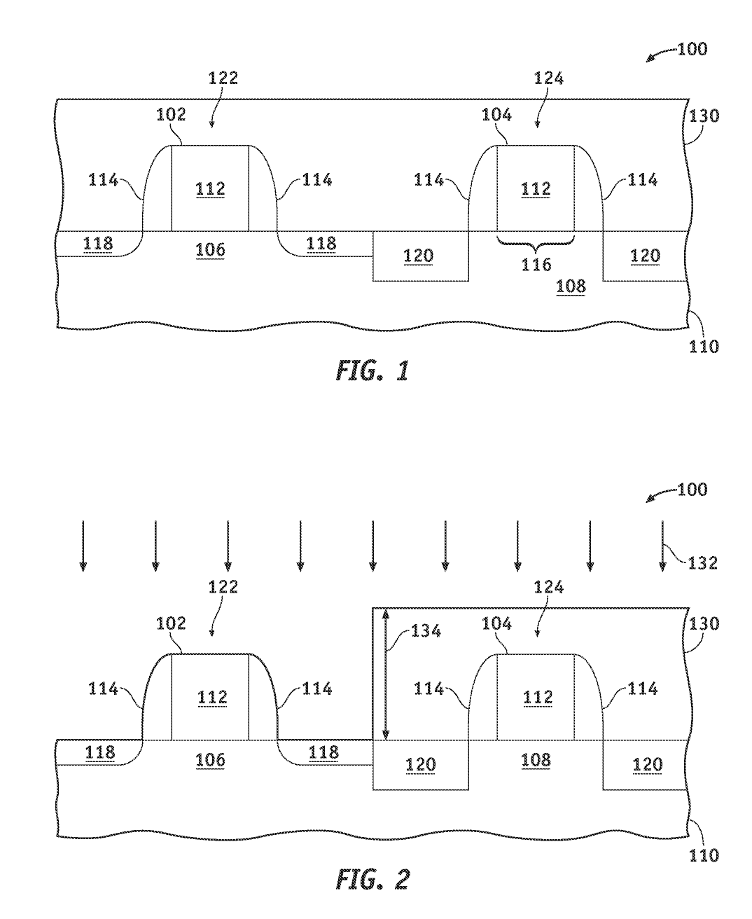

FIGS. 1-6 illustrate, in cross section, a method for fabricating a semiconductor device 100 in accordance with exemplary embodiments of the invention. For illustration purposes, the semiconductor device comprises two MOS transistors 122 and 124, although it will be understood that the various embodiments of the present invention are not so limited and can be used to fabricate any suitable semiconductor device. Although the term “MOS transistor” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a silicon substrate. While the fabrication of only two MOS transistors is illustrated, it will be appreciated that the method of FIGS. 1-6 can be used to fabricate any number of NMOS transistors and/or PMOS transistors. Various steps in the manufacture of MOS components are well known and so, in the interest of brevity, many conventional steps will only be mentioned briefly herein or will be omitted entirely without providing the well known process details.

Referring to FIG. 1, the method begins by forming a first gate stack 102 of MOS transistor 122 overlying a first region 106 of a semiconductor substrate 110 and a second gate stack 104 of MOS transistor 124 overlying a second region 108 of the substrate. The semiconductor substrate is preferably a silicon substrate wherein the term “silicon substrate” is used herein to encompass the relatively pure silicon materials typically used in the semiconductor industry as well as silicon admixed with other elements such as germanium, carbon, and the like. Alternatively, the semiconductor substrate can be germanium, gallium arsenide, or other semiconductor material. Semiconductor substrate 110 will hereinafter be referred to for convenience, but without limitation, as a silicon substrate. Silicon substrate 110 may be a bulk silicon wafer, or may be a thin layer of silicon on an insulating layer (commonly know as silicon-on-insulator or SOI) that, in turn, is supported by a carrier wafer. At least a surface of the silicon substrate is impurity doped, for example, by forming N-type well regions and P-type well regions for the fabrication of P-channel (PMOS) transistors and N-channel (NMOS) transistors, respectively. Gate stacks 102 and 104 may comprise, for example, gate insulators (not shown) disposed on the silicon substrate 110 and gate electrodes 112 disposed on the gate insulators. The gate stacks 102 and 104 also may comprise one or more spacers 114.

The second region 108 may comprise areas 120 of the silicon substrate 110 that, when subjected to high temperature process, experience a change in physical, chemical, and/or electrical properties. For example, as described above, second region 108 may comprise strained layers 120, such as SiGe layers or SiC layers, used to induce a stress in a channel 116 of second MOS transistor 124. In this regard, it may be desirable to protect the second region 108 from a subsequent high-temperature process so that strained layers 120 do not significantly relax. In another embodiment, areas 120 of second region 108 may comprise source and drain regions 120 disposed within the substrate 110 and forming channel 116. It may be desirable to protect the source and drain regions from a subsequent high-temperature process so that the impurity dopants of these areas do not significantly diffuse further into the silicon substrate. For purposes of illustration, areas 120 of second region 108 are referred to herein as strained layers 120 and first region 106 comprises source and drain regions 118 of MOS transistor 122 that have yet to be annealed to activate the dopant impurities therein.

As described above, to activate the dopant impurities of the source and drain regions 118 of first region 106, the first region 106 is subjected to a high-temperature annealing process such as LSA or RTA. Annealing of the source and drain regions 118 of first region 106 at the high temperatures necessary for activation can result in the significant relaxing of strained layers 120 of second region 108, thus compromising the stress the layers induce in channel 116. Accordingly, it is desirable to protect second region 108 so that it experiences temperatures no higher than a predetermined temperature while the source and drain regions of the first region are subjected to the high temperature annealing process. In other words, it is desirable to induce a predetermined temperature gradient between first region 106 and second region 108. In an exemplary embodiment of the present invention, a temperature gradient-inducing film 130 is globally formed overlying first region 106 and second region 108. A mask (not shown) is formed overlying temperature gradient-inducing film 130 and is patterned. Referring to FIG. 2, the patterned mask is used as an etch mask to remove film 130 overlying first region 106, while the film 130 remains overlying second region 108. The patterned mask then is removed.

The predetermined temperature gradient can be achieved by the type of material used for film 130. In one exemplary embodiment of the present invention, the temperature gradient-inducing film 130 is a thermally absorptive film that can absorb and retain incident heat, indicated by arrows 132, produced during the high-temperature annealing process. In other words, the film 130 demonstrates a resistance to heat conductivity, thus preventing heat from diffusing to the second region 108 of substrate 1 10. In this regard, the second region 108 experiences temperatures no higher than a predetermined temperature and thus a predetermined temperature gradient between first region 106 and second region 108 is achieved. For example, if the first region 106 is subjected to 1000° C. during the anneal process, film 130 can be configured so that the second region is kept below 400° C. and a predetermined temperature gradient of at least 600C is achieved. Examples of materials suitable for use as thermally absorptive temperature gradient-inducing films include silicon oxides, silicon nitrides, polycrystalline silicon, either individually or in combination as stacked layers.

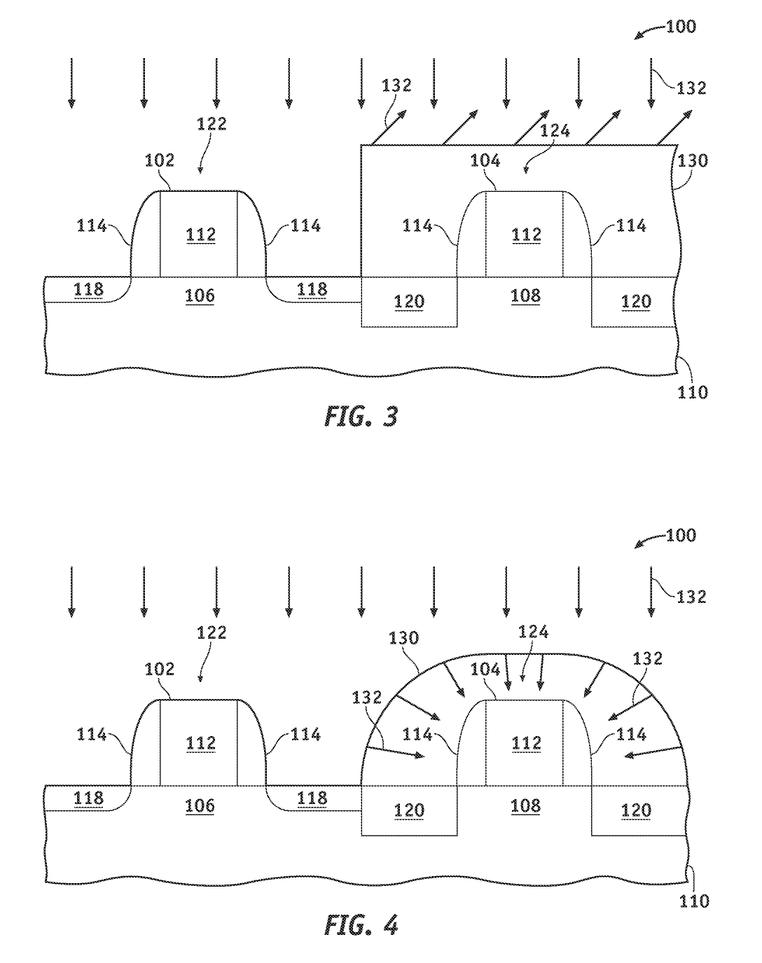

In another exemplary embodiment of the present invention, as illustrated in FIG. 3, the temperature gradient-inducing film is a reflective film that is configured to reflect incident heat 132 during the high temperature anneal process so that the second region 108 experiences temperatures no higher than a predetermined temperature and thus the predetermine temperature gradient is achieved. Examples of materials suitable for use as reflective temperature gradient-inducing films include silicon oxides, silicon nitrides, polycrystalline silicon, either individually or in combination as stacked layers.

Referring back to FIG. 2, in addition to being thermally absorptive and/or reflective, the temperature gradient-inducing film 130 can be configured to have a thickness, indicated by double-headed arrows 134, that facilitates production of the predetermined temperature gradient. In this regard, as the thickness of the film 130 increases, its resistance to thermal conductivity increases so that the temperature of the second region is maintained at temperatures no greater than a predetermined temperature.

Alternatively, it may be desirable to subject the second region 108 to a higher temperature than that to which the first region is subjected. For example, it may be desirable to subject the second region 108 to a higher temperature than the first region when strained layers in the second region are less prone to relaxation than those in the first region and require higher levels of dopant activation. Thus, thermal gradient-inducing film 130 may be formed of a thermally conductive material that conducts heat from the incident heat 132 of the thermal process and transfers it to the second region 108 so that second region 108 is maintained at a predetermined temperature or higher. Examples of thermally conductive materials suitable for forming film 130 include Examples of materials suitable for use as thermally absorptive temperature gradient-inducing films include silicon oxides, silicon nitrides, polycrystalline silicon, either individually or in combination as stacked layers. In another exemplary embodiment, as illustrated in FIG. 4, the thermal gradient-inducing film 130 also may be configured to have a shape that focuses the incident heat 132 at the second region 108 or, alternatively, at a structure, such as MOS transistor 124, on the second region 108. The desired shape of film 130 can be achieved by etching, conformal deposition, and/or low temperature anneal.

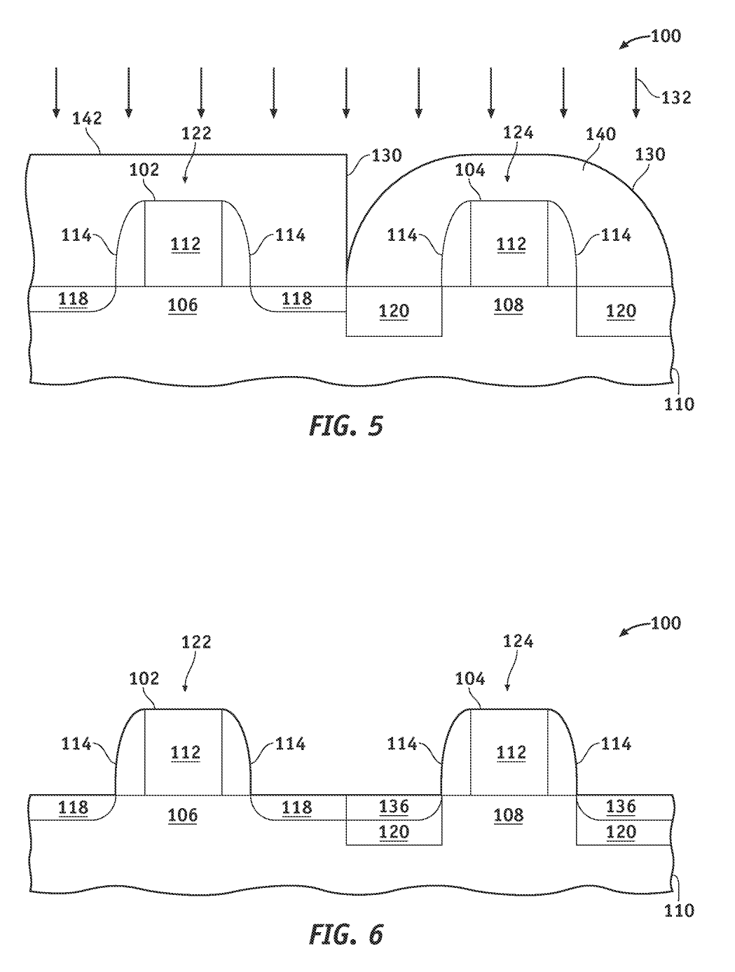

It will be appreciated that, in another exemplary embodiment of the present invention, two thermal gradient-inducing films may be used to decrease the temperature of first region 106 to no greater than a predetermined first temperature and increase the temperature of second region 108 to at least a predetermined second temperature. For example, referring to FIG. 5, a first thermal gradient-inducing film 130 overlying first region 106 may comprise a reflective or thermally absorptive film 142 and a second thermal gradient-inducing film 130 overlying second region 108 may comprise a thermally conductive film 140. In this regard, when subjected to incident heat 132 of a high temperature thermal process, a predetermined temperature gradient between the first region 106 and the second region 108 can be achieved.

Referring to FIG. 6, after the high temperature process has been performed, the thermal gradient-inducing film(s) 130 can be removed from semiconductor device 100 and fabrication of semiconductor device 100 may continue. For example, after activation of source and drain regions 118 and removal of film(s) 130, strained layers 120 can be subjected to ion implantation and annealing to form source and drain regions 136 therein.

Accordingly, methods for fabricating semiconductor devices that utilize thermal gradient-inducing films that induce a predetermined thermal gradient between a first region and a second region of a substrate of the semiconductor device have been provided. The films are configured so that, upon exposure to a thermal process, the first region is subjected to a higher temperature than the second region. In this regard, the second region is protected from thermal energy that would compromise physical, chemical, and/or electrical properties of the second region. In another exemplary embodiment, the films are configured so that, upon exposure to a thermal process, thermal energy can be concentrated at the second region to maximize the temperature the second region experiences. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for fabricating a semiconductor device, the method comprising the steps of:
providing a substrate having a first region and a second region;
forming a film overlying the second region and exposing the first region; and
subjecting the substrate to a thermal process wherein the film induces a predetermined thermal gradient between the first region and the second region.

2. The method of claim 1, wherein the steps of forming a film and exposing the first region comprise the steps of:
forming the film overlying the first region and the second region; and
removing a portion of the film overlying the first region.

3. The method of claim 1, wherein the step of forming a film comprises the step of forming a reflective film.

4. The method of claim 3, wherein the step of forming a reflective film comprises the step of forming a film comprising a material selected from the group consisting of a silicon oxide, a silicon nitride, polycrystalline silicon, and stacked layers thereof.

5. The method of claim 1, wherein the step of forming a film comprises the step of forming a thermally absorptive film.

6. The method of claim 5, wherein the step of forming a thermally absorptive film comprises the step of forming a film comprising a material selected from the group consisting of a silicon oxide, a silicon nitride, polycrystalline silicon, and stacked layers thereof.

7. The method of claim 1, wherein the step of forming a film comprises the step of forming the film so that it has a thickness that facilitates inducement of the predetermined thermal gradient.

8. The method of claim 1, wherein the step of forming a film comprises the step of forming a film that is configured to prevent incident heat from diffusing to the second region.

9. The method of claim 1, wherein the step of forming a film comprises the step of forming a film that is configured to concentrate incident heat to the second region.

10. The method of claim 9, wherein the step of forming a film comprises the step of forming a film of thermally conductive material.

11. The method of claim 10, wherein the step of forming a film of thermally conductive material comprises the step of forming a film comprising a material selected from the group consisting of a silicon oxide, a silicon nitride, polycrystalline silicon, and stacked layers thereof.

12. The method of claim 9, wherein the step of forming a film that is configured to concentrate incident heat to the second region comprises the step of forming the film so that it is configured to have a shape that focuses the incident heat at the second region.

13. A method of fabricating a semiconductor device, the method comprising the steps of:
providing a substrate having a first region and a second region;
forming a film overlying the first region and the second region;
removing a first portion of the film from the first region and leaving a second portion of the film overlying the second region; and
subjecting the substrate to a thermal process wherein the film causes the first region to experience a first predetermined temperature and the second region to experience a second predetermined temperature.

14. The method of claim 13, wherein the step of forming a film comprises the step of forming a reflective film.

15. The method of claim 13, wherein the step of forming a film comprises the step of forming a thermally absorptive film.

16. The method of claim 13, wherein the step of forming a film comprises the step of forming a film having a thickness that facilitates causing the second region to experience the second predetermined temperature.

17. The method of claim 13, wherein the step of forming a film comprises the step of forming a film that is configured to prevent incident heat from diffusing to the second region.

18. The method of claim 13, wherein the step of forming a film comprises the step of forming a film that is configured to concentrate incident heat to the second region.

19. The method of claim 18, wherein the step of forming a film comprises the step of forming a film of thermally conductive material.

20. The method of claim 18, wherein the step of forming a film that is configured to concentrate incident heat to the second region comprises the step of forming the film so that it is configured to have a shape that focuses the incident heat at the second region.

21. A method of fabricating a semiconductor device, the method comprising the steps of:
providing a substrate having a first region and a second region;
subjecting the substrate to a thermal process while inducing a predetermined thermal gradient between the first region and the second region.
